(19) United States
(12) Patent Application Publication
(10) Pub. No.: US 2014/0278171 A1
(43) Pub. Date: Sep. 18, 2014

(54) Frequency Adaptive Line Voltage Filters

(71) Applicants: Robert James Kahlke, Milwaukie, OR (US); Steven D. Baker, Beaverton, OR (US)

(72) Inventors: Robert James Kahlke, Milwaukie, OR (US); Steven D. Baker, Beaverton, OR (US)

(21) Appl. No.: 13/839,902

(22) Filed: Mar. 15, 2013

(51) Int. Cl. G01R 19/00; G01R 23/02

(52) U.S. Cl. CPC G01R 19/0053; G01R 23/02
USPC 702/64; 702/75

(57) ABSTRACT

A method for reducing noise from an electrical signal includes: obtaining a sampling rate for the electrical signal. The sampling rate is a rate at which voltage readings are obtained for the electrical signal. Each voltage reading comprises a data component and a noise component. A time interval is determined from the sampling rate. A number of voltage readings are obtained. Each voltage reading is obtained one time interval of time after a previous voltage reading is obtained. At each time interval: a voltage reading is obtained; the obtained voltage reading is applied to a low-pass filter; a noise value is obtained from the low-pass filter; and the noise value is subtracted from the voltage reading.

### BACKGROUND

When displaying physiological data received from a patient on a patient monitoring device, line noise at the patient monitoring device may be superimposed on the physiological data, resulting in an inaccurate display of the physiological data. Line voltage filters may be used to filter the line noise from the physiological data, but in order for the line voltage filters to accurately filter the line noise, power line frequency generally needs to be stable. However, in many countries, the power line frequency is not stable.

In addition, line voltage filters are typically able to filter harmonic noise from line voltage. Harmonics are generally sinusoidal waves. When line noise is in forms other than sinusoidal, the line voltage filters may not be accurate. In such situations, certain types of line noise, for example rectified sinusoids, distorted sinusoids and noise spikes are not removed from the line voltage by line voltage filters.

### SUMMARY

Embodiments of the disclosure are directed to a method implemented on an electronic computing device for estimating a line frequency of an electrical signal, the method comprising: on the electronic computing device, receiving an estimate of a first frequency of the electrical signal; determining a number of periods of the electrical signal to be examined, the number of periods corresponding to a frame of the electrical signal; determining a first number of voltage samples of the electrical signal to be obtained during a frame of the electrical signal; determining a phase shift between a first frame of the electrical signal and a second frame of the electrical signal, the phase shift comprising a second number of voltage samples in which the first frame and the second frame are out of phase; determining a time duration of the second frame; and determining a first estimate of the line frequency, the first estimate of the line frequency being equal to the number of periods divided by the time duration of the second frame.

In another aspect, a method implemented on an electronic computing device for reducing noise from an electrical signal includes: on the electronic computing device, determining a line frequency of the electrical signal; obtaining a first sampling rate for the electrical signal, the first sampling rate being a rate at which voltage readings are obtained for the electrical signal, each voltage reading comprising a data component and a noise component; determining a first time interval from the first sampling rate, the first time interval being equal to a reciprocal of the first sampling rate; determining a first sampling time and a second sampling time from the first sampling rate, the first sampling time being equal to the first time interval, the second sampling time being equal to a sum of the first sampling time and the first time interval; determining a first number line noise samples to be obtained within one frame of the electrical signal, the one frame of the electrical signal comprising either one period of the electrical signal or three periods of the electrical signal; obtaining a first voltage reading sample at the first sampling time; obtaining a second voltage reading sample at the second sampling time; determining a second sampling rate for the electrical signal, the second sampling rate being a rate at which simulated noise sample readings are obtained during the one frame of the electrical signal; determining a second time interval from the second sampling rate, the second time interval being a reciprocal of the second sampling rate; determining whether there is a first simulated sampling time between the first sampling time and the second sampling time; and when it is determined that there is a first simulated sampling time between the first sampling time and the second sampling time: obtaining a third voltage reading at the first simulated sampling time by interpolating the first voltage reading sample and the second voltage reading sample; applying the third voltage reading to a line filter; obtaining from the line filter a first noise value at the first simulated sampling time; and storing the first noise value in memory.

In yet another aspect, a method implemented on an electronic computing device for reducing noise from an electrical signal includes: determining a number of line noise samples; determining a sampling rate for the electrical signal; determining a time interval for the electrical signal, the time interval being equal to a reciprocal of the sampling rate; using the time interval to determine index array locations in a computer memory array, there being one index array location for each time interval time period within one frame of the electrical signal; obtaining a voltage reading at the sampling rate; applying the voltage reading to a line filter; determining a noise value for the voltage reading from the line filter; determining a first sampling time within a frame corresponding to the voltage reading; determining a second sampling time that is closest in time to the first sampling time; determining an array index location corresponding to the second sampling time; obtaining a simulated noise value from the computer memory array at the array index location; averaging the noise value obtained from the line filter and the simulated noise value; and storing the averaged noise value in the computer memory array at the array index location.

In yet another aspect, a method implemented on an electronic computing device for reducing noise from an electrical signal includes: obtaining a sampling rate for the electrical signal, the sampling rate being a rate at which voltage readings are obtained for the electrical signal, each voltage reading comprising a data component and a noise component; determining a time interval from the sampling rate, the time interval being equal to a reciprocal of the sampling rate; determining a number of voltage readings to be obtained within a first frame of the electrical signal, the first frame being any random frame in the electrical signal, the first frame of the electrical signal comprising an integer number of periods of the noise component of the electrical signal for which there are equally spaced voltage readings corresponding to the time interval, each voltage reading being obtained one time interval of time after a previous voltage reading is obtained; at each time interval within the first frame: obtaining a voltage reading; applying the obtained voltage reading to a low-pass filter; obtaining from the low-pass filter a noise value; and subtracting the noise value from the voltage reading.

In yet another aspect, a method for determining a line frequency of an electrical signal, the method includes: applying the electrical signal to a band-pass filter; sampling a first output signal of the band-pass filter at a first frequency; determining whether the sampled first output signal is a direct current (DC) signal; when a determination is made that the sampled first output signal is a DC signal, determining that the line frequency is equal to the first frequency; when a determination is made that the sampled first output signal is not a DC signal: determining a first beat frequency of the first output signal; sampling a second output signal of the band-pass filter at a second frequency, the second frequency being equal to a sum of the first frequency and the first beat frequency; determining whether the sampled second output signal is a DC signal; and when a determination is made that the sampled second output signal is a DC signal, determining that the power line frequency is equal to the sum of the first frequency and the first beat frequency or determining that the power line frequency is equal to the second frequency minus the first beat frequency.

The details of one or more techniques are set forth in the accompanying drawings and the description below. Other features, objects, and advantages of these techniques will be apparent from the description, drawings, and claims.

### DESCRIPTION OF THE DRAWINGS

FIG. 1 shows an example system that supports adaptive line filters and an averaging noise filter.

FIG. 2 shows example modules of the patient monitor device of FIG. 1.

FIG. 3 shows example sinusoidal waveforms corresponding to an example AC mains frequency of 60 Hz.

FIG. 4 shows a detailed section of the sinusoidal waveforms of FIG. 4.

FIG. 5 shows a method for interpolating noise values from an ECG input signal.

FIG. 6 shows another method for interpolating noise values from an ECG input signal.

FIG. 7 shows a third method for interpolating noise values from an ECG input signal.

FIGS. 8 and 9 show an alternative method for calculating noise values from an ECD input signal.

FIG. 10 shows an example flowchart for a method for determining an actual line frequency from an estimated AC mains frequency.

FIGS. 11-13 show an example flowchart for a method for removing noise from an electrical signal using interpolation.

FIG. 14 shows an example flowchart for a method for removing noise from an electrical signal using oversampling.

FIG. 15 shows example physical components of the patient monitor device of FIG. 1.

### DETAILED DESCRIPTION

The present disclosure is directed to a system and methods for accurately determining a real fundamental frequency of induced AC mains noise (as different from a known nominal fundamental frequency or an already approximated expected frequency) in an electrical signal and/or for removing one or both of sinusoidal and non-sinusoidal real line frequency noise from the electrical signal.

In some examples, the real fundamental frequency of the induced AC mains noise is determined by decimating the electrical signal at an expected line frequency, or sub-multiple thereof, to determine a beat frequency. The beat frequency corresponds to a difference between the expected line frequency and the real frequency of the induced AC mains noise in the electrical signal. The line frequency noise is removed by subtracting noise samples from the electrical signal. As used in this disclosure, the real frequency of the induced AC mains noise refers to the actual frequency of the induced AC mains noise. In this disclosure, line frequency and mains frequency may be used interchangeably.

In examples, an accurate determination of the line frequency involves the use of a variety of filters. Typically, a notch filter is used to block frequencies within a specified delta above and below the expected line frequency, while passing other frequencies of the electrical signal.

FIG. 1 shows an example system 100 which supports an averaging line frequency noise filter. The example system 100 includes an electrocardiogram (ECG) sensor 102 and a patient monitor device 104. The example ECG sensor 102 is typically attached to the body of a patient along with a plurality of other ECG sensors (not shown). The example patient monitor device 104 is a vital signs monitoring device.

The patient monitor device 104 receives ECG signals from ECG sensor 102 and displays a waveform corresponding to the ECG signals on a display screen of the patient monitor device 104. In examples, the ECG sensor 102 may be physically connected to the patient monitor device 104 via a wire or cable or the ECG sensor 102 may have a wireless connection to the patient monitor device 104. The patient monitor device 104 also receives physiological data from one or more other sensor devices attached to the patient. An example patient monitor device 104 is the Connex® Vital Signs Monitor from Welch Allyn, Inc. of Skaneateles Falls, N.Y.

The ECG signals transmitted from the ECG sensor 102 to the patient monitor device 104 are typically subject to electromagnetic interference. The electromagnetic interference may originate from one or more sources. For example, electromagnetic interference may originate in an AC power source for the patient monitor device 104. The AC power source, commonly referred to as an AC mains, may include harmonics that interfere with the ECG signals. The harmonics are typically whole number multiples of the AC mains frequency. For example, when the AC mains frequency is 60 Hz, harmonics may occur at 120 Hz and 180 Hz, etc. When the AC mains frequency is 50 Hz, harmonics may occur at 100 Hz and 150 Hz. Other sources of electromagnetic interference may include nearby equipment, for example fluorescent lights, that are powered by an AC power grid.

Harmonics are typically sinusoidal in form. However, line noise may not always be sinusoidal. In examples, synchronous spikes may sometimes be included in the line noise. Other types of waveforms, for example, rectified sinusoidal waveforms, may also be found in line noise.

FIG. 2 shows example modules of the patient monitor device 104. The patient monitor device 104 includes a transducer module 202, a mains frequency determination module 204, and a noise processing module 206.

The example transducer module 202 samples the electrical signal at the desired sampling rate and provides the sampled electrical signal to the mains frequency determination module 202 and the noise processing module 206.

The example mains frequency determination module 202 receives the electrical signal from the transducer module 202 at the desired sampling rate and with an estimated line frequency value, for example 50 Hz or 60 Hz, and determines the real value of the line frequency.

The example noise processing module 206 receives the electrical signal from the transducer module 202 and the real line frequency value from the mains frequency determination module 204 and removes noise from the electrical signal, as explained herein.

The mains frequency determination module 202 determines an actual line frequency of the AC mains by first down-sampling the sampled ECG waveform by choosing every Nth sample. The value of N chosen is dependent upon both the original sampling rate and upon the line frequency. The value of N is chosen such that for a sinusoidal waveform sampled and then down-sampled, the phase of the sinusoid in each down-sampled reading will be the same. For example, if the sampling rate is 1000 Hz and the line frequency is 50 Hertz, then taking every 20th sample (N=20) will always sample the line frequency sinusoid at a constant phase delay. If the line frequency is 60 Hertz, then taking every 50th sample (N=50) will always sample the line frequency sinusoid at a constant phase delay, although the sample will occur every third period of the line frequency sinusoid. A determination is made as to whether a beat frequency can be obtained as a result of the sampling. When a beat frequency can be found, a determination is made that an real AC mains frequency is equal to the expected AC mains frequency (50 Hz or 60 Hz) plus or minus the beat frequency.

FIG. 3 shows example sinusoidal waveforms 302, 304 corresponding to an example AC mains frequency of 60 Hz nominal. However to illustrate using the beat frequency to find the real frequency, the real AC mains frequency shown is slightly different from the nominal frequency. The waveforms 302, 304 are sampled at a frequency of 1000 Hz, corresponding to a sampling interval of 1 millisecond (mSec). Waveform 302 corresponds to a first three periods of an input waveform (from 0 seconds to 0.049 seconds) and waveform 304 corresponds to the next sequential three periods of the input waveform (from 0.05 seconds to 0.099 seconds). At 60 Hz, a period corresponds to 16 2/3 samples (16.667 mSec). Therefore, three periods correspond to 50 samples (0.05 seconds). In this disclosure, a frame refers to the number of whole periods of the nominal frequency AC mains waveform that corresponds to a whole number of samples. For a 50 Hz signal, a frame requires one period of the electrical signal. For a 60 Hz signal, a frame requires three periods of the electrical signal. In this disclosure, a frame corresponds to three periods of the electrical signal.

Waveform 302 shows 50 samples at 1 mSec intervals, a first sample 306 occurring at 0 seconds and a 50^{th} sample 308 occurring at 0.049 seconds. Sample 310 corresponds to a start of a second period of waveform 302, representing a sampling point just before waveform 302 transitions from a negative to a positive value for the second period.

Waveform 304 also shows 50 samples at 1 mSec intervals, a first sample 312 occurring at 0 seconds and a 50^{th} sample 314 occurring at 0.099 seconds. Sample 316 corresponds to a start of a second period of waveform 304, representing a sampling point just before waveform 304 transitions from a negative to a positive value for the second period.

In the example shown in FIG. 3, waveforms 302 and 304 have a frequency that is different from the expected AC mains frequency of 60 Hz. For example, samples 310 and 316 occur at different times relative to the start of the second period of waveforms 302 and 304.

FIG. 4 shows an expanded view of the waveforms 302 and 304 at the start of each second period. As can be seen from FIGS. 3 and 4, waveform 302 transitions from negative to positive at approximately 18.1 samples in the waveform 302 frame and waveform 304 transitions from negative to positive at approximately 19.4 samples in the waveform 304 frame.

By calculating an offset in zero crossing times for similar parts of a waveform, the real AC mains frequency may be calculated. In this example the offset equals 1.3 samples (19.4 minus 18.1). For an expected line frequency of 60 Hz, the time duration of one frame (3 periods) corresponds to 50 mSec (3*1000/60). However, the offset of 1.3 samples adds an additional 1.3 mSec (since each sample corresponds to a 1 mSec time duration). Therefore, the real line frequency (L) may be calculated by the following equation:

$$L = \frac{P [ cycles ]}{D [ seconds ]} \qquad ( 1 )$$

where P is the number of periods being examined, and D is the delay those periods require.

This equation indicates a real line frequency of 58.480 Hz (3/51.3 mSec).

In general, the following equations may be used to calculate a real line frequency from a known offset:

$$\begin{matrix} P = F [ frames ] * N [ \frac{periods}{frame} ] & ( 2 ) \\ D = P [ periods ] * T [ \frac{seconds}{periods} ] + E [ samples ] * \frac{1}{S} [ \frac{frames}{samples} ] * N [ \frac{periods}{frame} ] * T [ \frac{seconds}{period} ] & ( 3 )\end{matrix}$$

where:
S is the number of samples per frame,
T is the duration of a period of the line noise in seconds per period at the assumed line frequency,
F is the number of frames after the first frame during which a phase change occurs,
N is the number of periods per frame, and
E is the phase change in samples.

In the example shown in FIGS. 3 and 4, S is equal to 50 samples per frame, T is 16.666 mSec (corresponding to a 60 Hz signal), F is 1 (since the second frame is used immediately following the first frame used), N is 3 (corresponding to 3 periods per frame) and E is 1.3 (corresponding to an phase offset of 1.3 samples). Using the above equations:

$$P = F * N = 1 * 3 = 3 periods$$

$$D = 3 [ periods ] * 16.666 [ \frac{mSec}{period} ] + 1.3 [ samples ] * \frac{1}{50} [ \frac{frames}{samples} ] * 3 [ \frac{periods}{frame} ] * 16.666 [ \frac{mSec}{period} ]$$

$$D = 50 mSec + 1.3 mSec = 51.3 mSec$$

$$L = \frac{P [ cycles ]}{D [ seconds ]} = \frac{3 [ cycles ]}{51.3 [ mSec ]} = 58.480 Hz$$

The example noise processing module 206 uses a method of ensemble signal averaging to remove line noise from electrical signals provided by the transducer module 202. The method of ensemble signal averaging averages multiple frames together to create a line noise profile. This method relies on the assumption that the noise components in the ECG input signal repeats over multiple signal frames and does not change in morphology with each frame repetition. Because the ECG input signal is AC coupled, and because the heartbeat interval is not correlated with the duration of a frame, the cardiogenic component of the ECG input signal in each frame averaging location averages to zero over time. However, line noise components of the ECG input signal are correlated with the duration of a frame, and so the line noise component of the ECG input signal in each frame averaging location does not average to zero over time. The noise components as a result of this averaging can therefore be subtracted from the ECG input signal, leaving only the desired cardiogenic signal.

In the method of ensemble signal averaging used in the present disclosure, a frame size is determined for storing a line noise profile as the line noise profile is built up from input signal samples. Noise values are stored in memory, typically in an array structure. Each frame sample is stored in the array structure at an index location in the array structure corresponding to a time the sample would have been taken if it were possible to vary the sampling interval. Because an assumption is made that noise components in the frame repeat from frame to frame, noise values obtained for each sample of the frame are averaged with noise values stored in memory for previous frames at corresponding array positions.

Each frame corresponds to a predetermined number of periods of the AC mains noise. The number of periods in a frame is selected such that there are an integer number of AC mains periods in each frame and an integer number of array elements per frame. In order to ensure that there are an integer number of array elements per frame, a method of simulating a change in sample rate is utilized. For example, if the real AC mains frequency is 59.898 Hz and the number of samples is 50, in order to maintain an integer number of 50 samples per frame and therefore 50 array elements per frame for an estimated line frequency of 60 HZ, the sampling rate needs to be 998.3 Hz instead of 1000 Hz. At 59.898 Hz, a time duration for one period is 16.694 mSec (1000/59.9). The time duration of each sample is then 1.002 mSec (16.694*3/50), corresponding to a sampling frequency of 998.3 Hz (1000/1.002).

For this example if the actual sampling rate is 1000 Hz (corresponding to a time duration between pulses of 1000 mSec), a first noise sample is taken at time 0 and stored in a first array element. A second sample is taken at 1 mSec, but because the simulated sampling rate is 998.3 Hz, a simulated noise sample is needed at 1.002 mSec. Because the simulated noise sample occurs at a time other than when real samples are taken, a method of interpolation is used to determine a value for the simulated noise sample at 1.002 mSec.

Obtaining a frequency from a time duration comprises obtaining a quotient of one divided by the time duration when the time duration is in units of seconds, obtaining a quotient of 1000 divided by the time duration when the time duration is in units of mSec, obtaining a quotient of 1,000,000 divided by the time duration when the time duration is in units of microseconds, etc. In general the process of obtaining a frequency from a time duration involves calculating a reciprocal of the time duration, where the reciprocal comprises dividing one by the time duration, as discussed. In a similar manner, a process of obtaining a time duration from a frequency comprises determining a reciprocal of the frequency.

The systems and methods may also be used to remove one or both of sinusoidal and non-sinusoidal real frequency noise from the electrical signal. In this disclosure, for the methods of noise removal from the signal, the following assumptions are made:
1. The noise and non-noise components of the signal are combined additively.
2. The noise has a fundamental period after which it repeats with little or no change in morphology.
3. The non-noise component of the signal is not correlated with a fundamental period of the noise component of the signal.
4. The combined noise/non-noise signal is assumed to be AC coupled, i.e. has no DC component.
5. The noise signal does not need to be sinusoidal, or have any other specific shape.

Based on sampling rate, noise fundamental frequency (hereinafter noise frequency), and noise frequency variability, several examples may be considered.

In a first example, the noise period is known and does not vary, and the sampling period and the noise period are can be related by the following equation:

NPₛ=MPₙ

where Pₛ is the sampling period, and Pₙ is the noise period and M and N are small integers. For example, if Pₛ is 0.001 seconds (1000 Hz sampling rate) and Pₙ is 0.01666 seconds (60 Hz noise frequency) then the smallest value of M for which N is an integer is 3 and N is 50. For an example where M is 3 and N is 50, there are exactly three noise periods for every 50 samples. Thus, to properly perform ensemble signal averaging, a memory array of 50 values is created along with an index that points into the memory array and is incremented with each new sample. The index wraps back to the first sample after 50 samples have been collected. Each index corresponds to a time position within a frame of the electrical signal.

Each sample is low-pass filtered into a memory array location specified by the index. Assuming the morphology of the noise does not change quickly, after a few periods the array will contain an accurate representation of the noise signal with the non-noise component removed. The non-noise component can then be recovered by subtracting the current frame value from the current sample.

In a second example, the noise frequency continues to remain constant, but either the integers that solve the equation above are large (in which case it will take an unacceptable long time for the filter to converge on a true noise profile), or no integers exist (essentially, the integers are very large). For an example where the sampling frequency is 1375 Hz and the noise frequency is 60 Hz, 275 samples need to be collected before the period of the noise is resynchronized. This amounts to 12 periods of noise, and so will take four times longer to build the noise profile than if only 3 periods were required, as for the first example.

Ideally the solution would be to change the sampling rate to something that would allow small integers Pₙ and Pₛ to be found, however this is typically, unpractical. Therefore, a change in sampling rate may be simulated by interpolating between the real samples. If a simulated sampling rate of 1380 Hz is utilized, it is possible to obtain a complete period of the noise waveform in 23 samples. If the sampling interval is a non-integer value, for example, 1375.123456 Hz, interpolation may still be used.

In a third example, the noise frequency can slowly vary over a narrow pre-defined range. This example is essentially the same as the second example with the added complication of the varying noise frequency. Since the noise frequency is known to be within a given range, an implementation may be to assume a starting guess at the noise frequency (perhaps the middle of the range) and simulate a sampling rate that would allow a small number of noise periods equal to N times the simulated sampling period.

FIG. 5 shows a method 500 for interpolating signal values from an ECG input signal when there is one simulated signal sample in a time interval between two actual signal samples, using this interpolated value to update a noise profile, and then interpolation of the noise signal to get a noise value at the actual sample time. An object of the interpolation is to calculate a noise value that can be subtracted from an actual sample value.

The example method 500 shows four views of the method 500. In a first view 502, a value for the ECG input signal is obtained for two signal samples at a sampling rate of 1000 Hz. A first signal sample 510 has a value of A volts and a second signal sample 512 has a value of B volts. The samples A and B both include a cardiogenic component and a noise component. Based on the sampling rate of 1000 Hz, the second signal sample 512 is obtained 1 mSec after the first sample signal 510 is obtained.

The first view 502 also includes four simulated noise samples 514, 516, 518 and 520. Simulated noise sample 514 has a value of C volts and simulated noise sample 516 has a value of D volts. In examples, simulated noise samples 514 and 516 represent estimated noise voltages that are stored in computer memory array locations. The estimated noise voltages are obtained from a line filter and averaged over a period of time, typically around 1 second, to values that represent actual noise values. Because the cardiogenic component of the ECG input signal is AC coupled and not correlated with the period of the frame, the cardiogenic component of the ECG input signal averages to zero over the period of time at each index in the frame, leaving the noise component. Over the period of time, the estimated noise values average out to actual noise values, within a predetermined delta.

The simulated noise samples 514 and 516 are sampled at a rate such that an integer number of samples and an integer number of AC mains periods are obtained within one frame of the ECG input signal. For a nominal line frequency of 60 Hz and a sampling rate of 1000 Hz, a frame corresponds to three periods of the AC mains noise. Based on a real line frequency of 59.898 Hz, and a corresponding simulated sampling frequency of 998.3 Hz, the second simulated noise sample 516 is obtained 1.002 mSec after the first simulated noise sample 514 is obtained. Because the second simulated noise sample is obtained after the second actual sample 512, there is only one simulated sample between actual signal samples 510 and 512.

The second view 504 includes an interpolation point 522. The interpolation point 522 corresponds to an interpolation of signal samples 510 and 512 at a time corresponding to simulated noise sample 514. An example voltage E, representing a voltage at interpolation point 522 is then input to a low-pass filter at the frame index corresponding to interpolation point 522.

The third view 506 projects the interpolation point 522 down to point 524. Point 524 represents a new estimated noise value, corresponding to voltage F, based on inputting the example voltage E to the line filter. The line filter determines a noise value based on the voltage E and averages the noise value based on the voltage E with a noise value stored in the computer memory array at an index position corresponding to simulated noise sample 514. The result of the averaging is the new estimated noise value at point 524, corresponding to voltage F.

The fourth view includes a second interpolation point 528. The second interpolation point 528 corresponds to an interpolation of simulated noise samples 514 and 516 at a time corresponding to signal sample 512. The interpolation point 528 represents an interpolated noise voltage at the time of the signal sample 512. When averaged over a period of time, the interpolation point 528 corresponds to an actual noise value at the time of the signal sample 512.

A voltage G corresponding to the interpolation point 528 is then subtracted from the signal sample 512. The result of the subtraction represents the cardiogenic component of the ECG input signal for the signal sample 512.

The process shown in FIG. 5 is repeated for each actual signal sample. In addition, the noise values at each simulated sampling point (for example noise value 524 and simulated sampling point 514 and noise value 526 at simulated sampling point 516) are updated in the memory array over successive frames of the ECG input signal. Because an assumption is made that the noise is periodic over time, the noise values stored in the memory array average out to values corresponding to actual noise values for the ECG input signal.

FIG. 6 shows a method 600 for interpolating noise values from an ECG input signal when there are two simulated signal samples in a time interval between two actual signal samples. An object of the interpolation is to calculate a noise value that can be subtracted from an actual sample value. This example is for a nominal line frequency of 60 Hz. For a nominal line frequency of 60 Hz and a sampling frequency of 1000 Hz, as discussed, three AC mains periods of the input ECG signal are needed to obtain an integer number of simulated samples for the ECG input signal.

The example method 600 shows four views of the method 600. In a first view 602, a value for the ECG input signal is obtained for two signal samples at a sampling rate of 1000 Hz. A first signal sample 610 has a value of A volts and a second signal sample 612 has a value of B volts. The samples A and B both include a cardiogenic component and a noise component. Based on the sampling rate of 1000 Hz, the second sample 612 is obtained 1 mSec after the first signal sample 610 is obtained.

The first view 602 also includes four simulated noise samples 614, 616, 618 and 620. Simulated noise sample 614 has a value of C volts and simulated noise sample 616 has a value of D volts. In examples, simulated noise samples 614 and 616 represent estimated noise voltages that are stored in computer memory array locations. The estimated noise voltages are obtained from a line filter and averaged over a period of time, typically around 1 second, to values that represent actual noise values. Because the cardiogenic component of the ECG input signal is AC coupled and not correlated with the period of the frame, the cardiogenic component of the ECG input signal averages to zero over the period of time at each index in the frame, leaving the noise component. Over the period of time, the estimated noise values average out to actual noise values, within a predetermined delta.

The simulated noise samples 614 and 616 are sampled at a rate such that an integer number of samples and an integer number of AC mains periods are obtained within one frame of the ECG input signal. For a nominal line frequency of 60 Hz and a sampling rate of 1000 Hz, a frame corresponds to three periods of the AC mains noise. Based on a real line frequency of 59.898 Hz, and a corresponding simulated sampling frequency of 998.3 Hz, the second simulated noise sample 616 is obtained 1.002 mSec after the first simulated noise sample 614 is obtained. Because the second simulated noise sample is obtained before the second actual sample 612, there are two simulated samples between actual samples 610 and 612.

The second view 604 shows two interpolated points 622 and 624, corresponding to an interpolation of signal samples 610 and 612 at times corresponding to simulated noise samples 614 and 616, respectively. The associated interpolated voltages for points 622 and 624 are each applied to a low-pass filter at the frame indices corresponding to the interpolation points 622 and 624.

The third view 606 shows how the estimated line voltages at simulated sample points 614 and 616 change as a result of applying interpolated voltages 622 and 624 to the line filter. An output of the line filter for voltage 622 produces an estimated noise value that is averaged with a noise value stored in the computer memory array at an index position corresponding to the first simulated noise sample 614. The result of the averaging is an updated noise value 626. An output of the line filter for voltage 624 produces an estimated noise value that is averaged with a noise value stored in the computer memory array at an index position corresponding to the second simulated noise sample 616. The result of the averaging is an updated noise value 628.

The fourth view includes a second interpolation point 630. The second interpolation point 630 corresponds to an interpolation of simulated noise samples 616 and 618 at a time corresponding to signal sample 612. The interpolation point 630 represents an interpolated noise voltage at the time of the signal sample 612. When averaged over a period of time, the interpolation point 630 corresponds to an actual noise value at the time of the signal sample 612.

FIG. 7 shows a method 700 for interpolating noise values from an ECG input signal when there are no simulated signal samples in a time interval between two actual signal samples. An object of the interpolation is to calculate a noise value that can be subtracted from an actual sample value. This example is for an estimated line frequency of 60 Hz. For a nominal line frequency of 60 Hz and a sampling frequency of 1000 Hz, as discussed, three AC mains periods of the input ECG signal are needed to obtain an integer number of simulated samples for the ECG input signal.

The example method 700 shows four views of the method 700. In a first view 702, a value for the ECG input signal is obtained for two signal samples at a sampling rate of 1000 Hz. A first signal sample 710 has a value of A volts and a second signal sample 712 has a value of B volts. The samples A and B both include a cardiogenic component and a noise component. Based on the sampling rate of 1000 Hz, the second sample 712 is obtained 1 mSec after the first signal sample 710 is obtained.

The first view 702 also includes four simulated noise samples 714, 716, 718 and 720. Simulated noise sample 714 has a value of C volts and simulated noise sample 716 has a value of D volts. In examples, simulated noise samples 714 and 716 represent estimated noise voltages that are stored in computer memory array locations. The estimated noise voltages are obtained from a line filter and averaged over a period of time, typically around 1 second, to values that represent actual noise values. Because the cardiogenic component of the ECG input signal is AC coupled and not correlated with the period of the frame, the cardiogenic component of the ECG input signal averages to zero over the period of time at each index in the frame, leaving the noise component. Over the period of time, the estimated noise values average out to actual noise values, within a predetermined delta.

The simulated noise samples 714 and 716 are sampled at a rate such that an integer number of samples and an integer number of AC mains periods are obtained within one frame of the ECG input signal. For a nominal line frequency of 60 Hz and a sampling rate of 1000 Hz, a frame corresponds to three periods of the AC mains noise. Based on a real line frequency of 59.898 Hz, and a corresponding simulated sampling frequency of 998.3 Hz, the second simulated noise sample 716 is obtained 1.002 mSec after the first simulated noise sample 714 is obtained. Because the second simulated noise sample is obtained after the second actual sample 712, there are no simulated samples between actual samples 710 and 712.

FIG. 7 also shows views 704 and 706. However, because there are no simulated signal samples between actual signal samples 710 and 712, the line filter does not require updating. Therefore, estimated noise values 724 and 726 are the same as for view 702.

In view 708, an estimated noise value 728 is calculated at a time corresponding to actual signal sample 712. The estimated noise value 728 is an interpolation of the estimated noise values 724 and 726 at the time corresponding to actual signal sample 712. The estimated noise value 728 is subtracted from the signal sample voltage 712 to produce a cardiogenic component of the actual signal sample 712.

Any method using interpolation, such as methods 500, 600 and 700, typically introduces error into the computer memory array and into values extracted from the computer memory array. One way to reduce error is to use a method of oversampling instead of interpolation. Oversampling consists of increasing a number of simulated samples during a frame by a constant value, for example, by a value of 10. Thus, for an example where simulated samples occur every 1.002 mSec (1002 microseconds), with oversampling simulated samples may occur every 100.2 microseconds. Over a period of time, noise values are calculated for each of the oversampled simulated samples and the noise values are stored in computer memory array locations for each of the oversampled simulated samples. Thus, with oversampling, many more computer memory array locations are used than for methods 500, 600, 700. For example, 500 computer memory array locations may be used instead of 50 computer memory array locations.

However, instead of using interpolation for each simulated sample, when a new actual sample is received, a timestamp corresponding to the new actual sample is used to find a simulated sample that is closest in time to the new actual sample. When the simulated sample that is closest in time to the new actual sample is determined, noise data for the new actual sample is determined and the noise data is averaged into a computer memory array location corresponding to the simulated sample that is close in time to the new actual sample. In examples, closest in time may refer to a simulated sample with a timestamp immediately preceding the new actual sample. In other examples, closest in time may refer to a simulated sample immediately following the new actual sample.

The noise data for the new actual sample is obtained by inputting a voltage corresponding to the new actual sample to a line filter and receiving an estimated noise value from the line filter. The line filter determines the estimated noise value by low pass filtering the current noise value in computer memory at the same index in the frame with the actual sample voltage.

One way to accomplish this low pass filtering would be by multiplying the actual sample voltage by a first weighting factor and adding the result of the multiplication to a product of a noise value in the computer memory location and a second weighting factor, wherein the two weighting factors add to 1. In examples, the first weighting factor may be 0.8 and the second weighting factor may be 0.2. In other examples, the first weighting factor may be 0.9 and the second weighting factor may be 0.1. Other weighting factors may be used.

FIG. 8 shows a method 800 for providing a more accurate method of calculating line noise than methods 500, 600 and 700. FIG. 8 shows part of an AC mains noise profile 802 with a plurality of simulated sampling points. FIG. 8 also shows timestamps 804 (with values in microseconds) corresponding to each simulated sampling point and an index 806 corresponding to computer memory array locations for each simulated sample.

When an actual line frequency is determined to be different from the nominal AC mains frequency, over a period of time, noise values will be calculated for each of the computer memory array locations corresponding to simulated samples. For example, for a nominal line frequency of 60 Hz, three periods are needed to produce an integer number of samples. For an example where 50 actual samples are used over the three periods and where 500 simulated samples are used, when the actual line frequency is determined to be 56.4 Hz, each simulated sample occurs at approximately 106 microsecond intervals ([(1000/56.4)*3]/500)). For example, FIG. 8 shows a first simulated sample at 0 seconds, a second simulated sample at 106 microseconds, a third simulated sample at 213 microseconds, etc.

When an actual sample 810 occurs at 0.001 seconds a voltage value for the actual sample is applied to a line filter value at the closest time stamp. Sample index 9 occurs at 957 microseconds, which is the closest sample to the actual time stamp of 0.001 seconds. The existing noise value 808 is low pass filtered with the new input voltage 810. The result of this filtering 812 is stored in the computer memory array location for sample index 9.

If an infinite impulse response (IIR) filter is used to perform the low pass filtering the line filter calculates the noise value 812 by obtaining a product of the voltage value for the actual sample 810 and a first weighting factor. In examples, the first weighting factor may be 0.1 or 0.2. When the first weighting factor is 0.1, the new noise value 812 is obtained by multiplying the existing noise value 808 by 0.9 (1 minus the first weighting factor) and adding the product of the multiplication to the product of the voltage value for the actual sample and the first weighting factor. When the first weighting factor is 0.2, the new noise value 812 is obtained by multiplying the noise value 808 by 0.8 and adding the product of the multiplication to the product of the voltage value for the actual sample and the first weighting factor. In this disclosure, calculating a noise value using a weighting factor in this manner, is referred to as using a weighted average to obtain the noise value.

FIG. 9 shows example noise and index values for the ECG input signal approximately 50 mSec later. For a nominal line frequency of exactly 60 Hz, 50 mSec corresponds to exactly one frame (3 periods) of the ECG input signal. However, when the real line frequency is not equal to the nominal line frequency of 60 Hz, but instead is 56.4 Hz as in this example, the start of the next frame occurs 53.191 mSec later (1000/56.4*3). As a result, a first actual sample in the second frame occurs at sample index 8 (corresponding to 54043 microseconds) instead of at sample index 9 for the first frame.

The closest simulated sample to the first actual sample in the second frame is at sample index 8, one sample index value before sample index 9. According to the method shown in FIG. 9, the first actual sample in the second frame 910 is applied to a line filter associated with sample index 8. An example signal value 910 is obtained. The example signal value 910 is averaged with a noise value 908 stored in the computer memory array location corresponding to sample index 8. The result of the averaging, noise value 912, is stored in the computer memory array location corresponding to sample index 8.

In this manner, over a plurality of frames, noise values are calculated for each of the simulated noise computer memory array locations, 500 locations in this example. As a result, over a period of time, typically around ten seconds, an accurate representation of the noise associated with the ECG input signal is built up and stored in the computer memory array.

To initialize the filter more quickly, it may be desirable for a period of time, or under certain circumstances, to create more than one simulated sample for each actual sample obtained instead of creating just the closest simulated sample. For example, when a new signal value is obtained, linear interpolation may be used to create simulated samples between the new signal value and the previous signal value. The simulated samples are then used to update all the noise values that have time stamps between the two signal values.

FIG. 10 shows an example flowchart for a method 1000 for determining a real line frequency from a nominal AC mains frequency. Typically, the nominal AC mains frequency is either 50 Hz or 60 Hz. The real frequency may vary from the nominal AC mains frequency due to power generation conditions in some countries in the world.

At operation 1002, an electrical signal is applied to a band-pass filter. In examples, the electrical signal may be an output from an ECG sensor. The electrical signal may be applied to a patient monitoring device where the ECG data may be displayed. In examples, the electrical signal may include an additive noise component. The noise component may originate from one of several sources, including AC current used to power the patient monitoring device and electromagnetic interference (EMI) from nearby equipment, such as fluorescent lights, that are powered by an AC grid. The band-pass filter is centered at the nominal AC mains frequency.

At operation 1004, data samples are obtained for a first frame of AC mains noise. As discussed, a frame corresponds to an integer number of periods of the electrical signal that corresponds to an integer number of samples, regardless of the AC mains frequency. For a 60 Hz signal, a frame requires three complete periods of AC mains noise.

At operation 1006, the second negative to positive zero crossing of the signal is located in the frame. There are approximately three negative to positive zero crossings in the frame. The second negative to positive zero crossing is selected so that there is sufficient signal on both sides of the zero crossing for future operations.

At operation 1008, voltage values and time stamps are obtained for data points that bound the zero crossing.

At operation 1010, interpolation is used to determine a time corresponding to the zero crossing. The time corresponding to the zero crossing is an interpolation of the timestamps and voltage values obtained in operation 1008.

At operation 1012, data samples are obtained for an additional frame of AC mains noise, for example the next consecutive frame of the AC mains noise.

At operation 1014, the second negative to positive zero crossing of the signal is located in the additional frame of AC mains noise.

At operation 1016, voltage values and time stamps are obtained for data points that bound the zero crossing for the additional frame of AC mains noise.

At operation 1018, interpolation is used to determine a time corresponding to the zero crossing. The time corresponding to the zero crossing is an interpolation of the timestamps and voltage values obtained in operation 1016.

At operation 1020, a determination is made as to whether data from enough frames have been collected to determine the real AC mains noise frequency. If the real AC mains frequency is equal to the nominal frequency, then the time of the zero crossings for the first frame and a current frame have the same displacement from the beginning of the frames. If the real AC mains frequency is different from the nominal frequency, then the zero crossing in the current frame is moving either earlier or later in the current frame with each frame collected. If the zero crossing has moved, for example, by at least one third of a frame, or if data has been obtained for a certain number of frames, for example, 25 frames, then a determination is made that enough frames have been gathered and an accurate determination of the real AC mains frequency can be made.

At operation 1022, when a determination is made that no additional data is needed, the real AC mains line frequency is determined by examining the relative offset of the zero crossings in the first frame collected and the last frame collected and the number of frames that have been collected.

At operation 1020, when a determination is made that more data is needed, control advances to operation 1012 and data is obtained for an additional frame of AC mains noise.

FIGS. 11-13 show an example flowchart for a method 1100 for removing noise from an electrical signal when one simulated sampling time occurs within two actual sampling times. In the method 1100, the electrical signal an ECG signal. The noise removed from the electrical signal may be any combination of sinusoidal and non-sinusoidal noise with a period corresponding to the real line frequency.

At operation 1102, the line frequency of the electrical signal is determined. The line frequency of the electrical signal may be determined using a method similar to method 1000 of FIG. 10, which is consistent with equations 1-3 above.

At operation 1104, a simulated sampling rate is determined for the electrical signal. The simulated sampling rate corresponds to a rate at which an integer number of voltage samples are obtained for one frame of the electrical signal. One frame of the electrical signal corresponds to three periods of the AC mains line noise. For a 50 Hz line frequency, an example sampling rate is 1000 Hz, corresponding to a sample every 1 mSec, for a total of 60 samples per a single period of the 50 Hz electrical signal.

At operation 1106, first and second sampling times are obtained from the sampling rate. In examples, a first sampling time may be at zero seconds and a second sampling time may be at 1 mSec. As another example, the first sampling time may be at 1 mSec and the second sampling time may be at 2 mSec.

At operation 1108, signal voltage readings are obtained at the first and second sampling times. The signal voltage readings are typically obtained from an analog to digital converter (ADC). The signal voltage typically includes both a cardiogenic component and an additive AC mains frequency noise component. In examples, the noise component includes both sinusoidal and non-sinusoidal noise.

An assumption is made that AC mains noise in the electrical signal repeats over a series of frames of the electrical signal. Because the cardiogenic component of the electrical signal is AC coupled, the cardiogenic component in the electrical signal averages out to a value of zero. Therefore, for signal values taken at a constant delay from the beginning of a frame, the cardiogenic component averages zero, and the AC mains noise component averages to the true noise value.

At operation 1110, a simulated sampling rate is determined for the electrical signal. The simulated sampling rate is equal to the real line frequency (as determined at operation 1102), multiplied by the integer number of samples required for one frame of the electrical signal. In examples, for an estimated 50 Hz line frequency and a 1000 Hz sampling rate, the number of line samples obtained during one frame (three periods in this example) of the electrical signal is 60 samples. For example, for an real line frequency of 59.9 Hz, a time duration of three periods is 60.12 mSec and a time duration of each of the 60 samples is 1.002 mSec. A time duration of 1.002 mSec per simulated sample corresponds to a simulated sampling rate of 998.3 Hz.

At operation 1112, a first simulated sampling time and a second simulated sampling time is obtained. In examples, based on a simulated sampling rate of 998 Hz, when the first simulated sampling time is zero, the second simulated sampling time is 1.002 mSec. Similarly, when the first simulated sampling time is 1.002 mSec, the second simulated sampling time is 2.004 mSec.

At operation 1114, a determination is made as to whether one simulated sampling point is within a time range of the two actual samples. Specifically, a determination is made as to whether the first simulated sampling time comes after the first sampling time but before the second sampling time and whether the second sampling time comes after the second sampling time.

When a determination is made at operation 1114 that one simulated sampling point is within the time range of the two actual samples, at operation 1116, a signal voltage at the first simulated sampling time is interpolated from the two actual signal voltage readings. Referring to FIG. 5, an example of operation 1116 comprises determining an interpolated signal voltage 522 from actual signal samples 510 and 512.

At operation 1118, the interpolated signal voltage at operation 1116, for example signal voltage 522, is applied to a line filter. The line filter is typically a one pole IIR low pass filter. The line filter provides an estimated value of a noise component of the signal voltage 522.

At operation 1120, the estimated noise component output of the line filter at the first simulated sampling time is received. The estimated noise component output of the line filter is based on a configuration of the line filter.

For example, for a line filter with a filter coefficient of 0.8, the estimated noise component output of the line filter is equal to 0.2 multiplied by the signal voltage 522 plus 0.8 multiplied by a previous estimated noise value. The previous estimated noise value is stored in a computer memory array location with an array index corresponding to the first simulated sampling time.

As another example, for a filter coefficient of 0.9, the estimated noise component output of the line filter is equal to 0.1 multiplied by the signal voltage 522 plus 0.9 multiplied by a previous estimated noise value. The previous estimated noise value is a noise value stored in a computer memory array location with an array index corresponding to the first simulated sampling time. The estimated noise component output of the line filter constitutes an updated estimated noise component output, for example updated estimated noise value 524. Over time, the estimated noise component output approaches a value corresponding to an actual noise component value at the first simulated sampling time.

At operation 1122, the noise filter output of the line filter from operation 1120 is stored at a first index position in the computer memory array. The first index position corresponds to a memory location for a noise value for the first simulated sampling time.

At operation 1124, a noise value is obtained at a second simulated sampling time, for example at simulated sampling time 516. The noise value is stored in a computer memory array location corresponding to the second simulated sampling time. This noise value is an estimated value for a noise component of the ECG input signal at the second simulated sampling time.

At operation 1126, a noise value is calculated at the second sampling time, for example at a sampling time corresponding to signal sample 512. The noise value is calculated by interpolating noise values stored at the first simulated sampling time (for example simulated sampling time 514) and at the second simulated sampling time (for example simulated sampling time 516) at the second sampling time (for example at a sampling time corresponding to signal sample 512). In the example method 500, the interpolated noise value at the second sampling time is designated as 528.

At operation 1128, the interpolated noise value at the second sampling time is subtracted from the signal voltage reading at the second sampling time. For example, interpolated noise value 528 is subtracted from signal sample 512. The result of the subtraction comprises an estimate of the cardiogenic component of the signal sample 512 at the second sampling time. Over time, as the simulated noise values at the first and second simulated sampling times become closer to an actual value of noise levels at the first and second simulated sampling times, the estimate of the cardiogenic component of the signal voltage at the second sampling time becomes closer to an actual value of the cardiogenic component of the signal sample 512 at the second sampling time.

When a determination is made at operation 1114 that one simulated sampling point is not within the time range of the two actual samples, at operation 1130, a determination is made as to whether two simulated sampling points are within the time range of the two actual samples.

When a determination is made at operation 1130 that two simulated sampling points are within the time range of the two actual samples, at operation 1132, a signal voltage at the first simulated sampling time is interpolated from the two actual signal voltage readings. Referring to FIG. 6, an example of operation 1132 comprises determining an interpolated signal voltage 622 from actual signal voltages 610 and 612.

At operation 1134, the interpolated signal voltage at operation 1132, for example signal voltage 622, is applied to a line filter. The line filter provides an estimated value of a noise component of the signal voltage 622.

At operation 1136, the estimated noise component output of the line filter at the first simulated sampling time is received. The estimated noise component output of the line filter is based on the configuration of the line filter, as discussed previously herein.

At operation 1138, the noise filter output of the line filter from operation 1136 is stored at a first index position in the computer memory array. The first index position corresponds to a memory location for a noise value for the first simulated sampling time.

At operation 1140, a signal voltage at the second simulated sampling time is interpolated from previous signal voltage readings. Referring to FIG. 6, an example of operation 1140 comprises determining an interpolated signal voltage 624 from actual signal voltages 610 and 612.

At operation 1142, the interpolated signal voltage at operation 1140, for example signal voltage 624, is applied to a line filter. The line filter provides an estimated value of a noise component of the signal voltage 624.

At operation 1144, the estimated noise component output of the line filter at the first simulated sampling time is received. The estimated noise component output of the line filter is based on the configuration of the line filter, as discussed previously herein.

At operation 1146, the noise filter output of the line filter from operation 1144 is stored at a second index position in the computer memory array. The second index position corresponds to a memory location for a noise value for the second simulated sampling time.

At operation 1148, a noise value is obtained at a third simulated sampling time, for example at simulated sampling time 618. The noise value is stored in a computer memory array location corresponding to the third simulated sampling time. This noise value is an estimated value for a noise component of the ECG input signal at the third simulated sampling time.

At operation 1150, a noise value is calculated at the second sampling time, for example at a sampling time corresponding to signal sample 612. The noise value is calculated by interpolating noise values stored at the second simulated sampling time (for example simulated sampling time 616) and at the third simulated sampling time (for example simulated sampling time 618) at the second sampling time (for example at a sampling time corresponding to signal sample 612). In the example method 600, the interpolated noise value at the second sampling time is designated as 630.

At operation 1152, the interpolated noise value at the second sampling time is subtracted from the signal voltage reading at the second sampling time. For example, interpolated noise value 630 is subtracted from signal voltage 612. The result of the subtraction comprises an estimate of the cardiogenic component of the signal voltage 612 at the second sampling time. Over time, as the simulated noise values at the first and second simulated sampling times become closer to an actual value of noise levels at the first and second simulated sampling times, the estimate of the cardiogenic component of the signal voltage at the second sampling time becomes closer to an actual value of the cardiogenic component of the signal voltage 612 at the second sampling time.

When a determination is made at operation 1130 that two simulated sampling points are not within the time range of the two actual samples, at operation 1154, a determination is made as to whether no simulated sampling points are within the time range of the two actual samples.

At operation 1154, when a determination is made that there are no simulated sampling times within the range of the two actual samples, at operation 1156, a noise value is obtained at a first simulated sampling time from the computer memory array. For example, referring to FIG. 7 for method 700, a noise value 724, corresponding to the first simulated sampling time 714, is obtained from the computer memory array.

At operation 1158, a noise value is obtained at a second simulated sampling time from the computer memory array. For example, a noise value 726, corresponding to the second simulated sampling time 716, is obtained from the computer memory array.

At operation 1160, a noise value is determined at the second sampling time via an interpolation of noise values at the first and second simulated sampling times. For example, a noise value 728 is calculated from an interpolation of noise values 724 and 726.

At operation 1162, the interpolated noise value from operation 1160 is subtracted from the signal voltage reading at the second sampling time. For example the noise value 728 is subtracted from the signal voltage reading 712.

FIG. 14 shows an example flowchart for a method 1400 for improving noise reduction from an electrical signal. In the method 1400, an increased number of simulated sampling points are used compared with method 1100. The increased number of simulated sampling points, typically an integer value of at least 10 times the simulated sampling points of method 1100, provides for a simulated oversampling of the electrical signal.

At operation 1402, the simulated noise samples of method 1100 are increased per frame by an integer value of at least 10 times simulated noise samples of method 1100. For example, if method 1100 used 50 simulated noise samples per frame, 500 simulated noise samples per frame may be used in method 1400.

At operation 1404, a simulated sampling rate is determined for the number of noise samples of operation 1402. The sampling rate is determined by determining a time period per frame for the real line frequency and dividing the number of noise samples by the time period per frame.

At operation 1406, memory array locations are determined for each of the number of noise samples. Each memory array location has an associated index that can be used to access the memory array location.

At operation 1408, a voltage reading is obtained. The voltage reading is obtained at a sampling time corresponding to a sampling time for method 1100. As discussed, for an estimated 50 Hz signal, at a 1000 Hz sampling rate, there are 60 samples per frame, where one frame equals three periods. For an estimated 60 Hz signal, at a 1000 Hz sampling rate, there are 50 samples per frame, where one frame equals three periods.

At operation 1410, a noise sampling time is determined that is closest to the time of the voltage reading. For example, per FIG. 8, if the voltage reading 810 occurred at a time of 1000 microseconds, a noise sampling time at 957 microseconds, corresponding to sample index 9, may be used.

At operation 1412, a memory array location corresponding to the noise sampling time is determined. For example, per FIG. 8, the memory array location corresponding to the noise sampling time at 957 microseconds is the memory array location having sample index 9.

At operation 1414, a noise value is obtained from the memory array location determined at operation 1412. The noise value obtained represents a noise value from previous frames of the electrical signal. For an initial calculation, the noise value obtained is zero.

At operation 1416, the noise value obtained for the voltage reading of operation 1408 is averaged with the noise value obtained from the memory location determined at operation 1414. In examples, averaging comprises determining a first product by multiplying the noise value obtained for the voltage reading of operation 1408 by a first weighting factor, determining a second product by multiplying the noise value obtained from the memory location determined at operation 1414 and adding the first product and the second product.

At operation 1418, the averaged noise value is stored in the memory array location. For example, the sum of the first product and the second product of operation 1418 is stored in the memory array location having sample index 9.

At operation 1420, the noise value from operation 1418 is subtracted from the signal voltage reading from operation 1408.

FIG. 15 illustrates example physical components of the patient monitor device 104. As illustrated in the example of FIG. 15, the patient monitor device 104 includes at least one central processing unit (“CPU”) 1502, a system memory 1508, and a system bus 1522 that couples the system memory 1508 to the CPU 1502. The system memory 1508 includes a random access memory (“RAM”) 1510 and a read-only memory (“ROM”) 1512. A basic input/output system contains the basic routines that help to transfer information between elements within the patient monitor device 104, such as during startup, is stored in the ROM 1512. The patient monitor device 104 further includes a mass storage device 1514. The mass storage device 1514 is able to store software instructions and data.

The mass storage device 1514 is connected to the CPU 1502 through a mass storage controller (not shown) connected to the bus 1522. The mass storage device 1514 and its associated computer-readable data storage media provide non-volatile, non-transitory storage for the patient monitor device 104. Although the description of computer-readable data storage media contained herein refers to a mass storage device, such as a hard disk or solid state disk, it should be appreciated by those skilled in the art that computer-readable data storage media can be any available non-transitory, physical device or article of manufacture from which the central display station can read data and/or instructions.

Computer-readable data storage media include volatile and non-volatile, removable and non-removable media implemented in any method or technology for storage of information such as computer-readable software instructions, data structures, program modules or other data. Example types of computer-readable data storage media include, but are not limited to, RAM, ROM, EPROM, EEPROM, flash memory or other solid state memory technology, CD-ROMs, digital versatile discs (“DVDs”), other optical storage media, magnetic cassettes, magnetic tape, magnetic disk storage or other magnetic storage devices, or any other medium which can be used to store the desired information and which can be accessed by the patient monitor device 104.

According to various embodiments of the invention, the patient monitor device 104 may operate in a networked environment using logical connections to remote network devices through the network 1520, such as a local network, the Internet, or another type of network. The patient monitor device 104 may connect to the network 1520 through a network interface unit 1504 connected to the bus 1522. It should be appreciated that the network interface unit 1504 may also be utilized to connect to other types of networks and remote computing systems. The patient monitor device 104 also includes an input/output controller 1506 for receiving and processing input from a number of other devices, including a keyboard, a mouse, a touch user interface display screen, or another type of input device. Similarly, the input/output controller 606 may provide output to a touch user interface display screen, a printer, or other type of output device.

As mentioned briefly above, the mass storage device 1514 and the RAM 1510 of the patient monitor device 104 can store software instructions and data. The software instructions include an operating system 1518 suitable for controlling the operation of the patient monitor device 104. The mass storage device 1514 and/or the RAM 1510 also store software instructions, that when executed by the CPU 1502, cause the patient monitor device 104 to provide the functionality of the patient monitor device 104 discussed in this document. For example, the mass storage device 1514 and/or the RAM 1510 can store software instructions that, when executed by the CPU 1502, cause the patient monitor device 104 to display received physiological data on the display screen of the patient monitor device 104.

Although various embodiments are described herein, those of ordinary skill in the art will understand that many modifications may be made thereto within the scope of the present disclosure. Accordingly, it is not intended that the scope of the disclosure in any way be limited by the examples provided.

1. A method implemented on an electronic computing device for estimating a frequency of an electrical signal, the method comprising:
on the electronic computing device, receiving an estimate of a first frequency of the electrical signal;
determining a number of periods of the electrical signal to be examined, the number of periods corresponding to a frame of the electrical signal;
determining a first number of voltage samples of the electrical signal to be obtained during a frame of the electrical signal;
determining a phase shift between a first frame of the electrical signal and a second frame of the electrical signal, the phase shift comprising a second number of voltage samples in which the first frame and the second frame are out of phase;
determining a time duration of the second frame; and
determining a first estimate of the line frequency, the first estimate of the frequency being equal to the number of periods divided by the time duration of the second frame.

2. The method of claim 1, further comprising:
performing one or more iterations of determining a phase shift between the first frame of the electrical signal and the second frame of the electrical signal, the phase shift comprising a number of voltage samples in which the first frame and the second frame are out of phase, each of the one or more iterations being performed at a different frequency of the electrical signal, the first of the one or more iterations being performed at the first estimate of the line frequency;
determining an estimate of the frequency for each of the one or more iterations; and
performing the one or more iterations and determining an estimate of the frequency for each of the one or more iterations until the frequency and estimated frequency are within a predetermined frequency delta.

3. The method of claim 1, wherein determining a phase shift between the first frame of the electrical signal and a second frame of the electrical signal comprises:
determining a first time for a zero crossing of the first frame of the electrical signal, the first time being a time from a start of the first frame to a time when the electrical signal of the first frame changes from a negative voltage to a positive voltage;
determining a number of first samples of the electrical signal corresponding to the first time;
determining a second time for a zero crossing of the second frame of the electrical signal, the second time being a time from the start of the second frame to a time when the electrical signal of the second frame changes from a negative voltage to a positive voltage; and
determining a number of second samples of the electrical signal corresponding to the second time,
wherein the phase shift is equal to a difference between the number of first samples and the number of second samples.

4. The method of claim 1, wherein determining a time duration of the second frame comprises:
determining a first time duration of the first frame of the electrical signal;
determining a second time duration of the second number of voltage samples; and
adding the first time duration and the second time duration.

5. A method implemented on an electronic computing device for reducing noise from an electrical signal, the method comprising:
obtaining a first sampling rate for the electrical signal, the first sampling rate being a rate at which voltage readings are obtained for the electrical signal, each voltage reading comprising a data component and a noise component;
determining a first time interval from the first sampling rate, the first time interval being equal to a reciprocal of the first sampling rate;
determining a first sampling time and a second sampling time, the first sampling time occurring at any random point in the electrical signal, the second sampling time being equal to a sum of the first sampling time and the first time interval;
determining a first number of noise samples to be obtained within one frame of the electrical signal, the one frame of the electrical signal comprising either one period of the electrical signal or three periods of the electrical signal;
obtaining a first voltage reading sample at the first sampling time;
obtaining a second voltage reading sample at the second sampling time;
determining a second sampling rate for the electrical signal, the second sampling rate being a rate at which simulated noise sample readings are obtained during the one frame of the electrical signal;
determining a second time interval from the second sampling rate, the second time interval being a reciprocal of the second sampling rate;
determining whether there is a first simulated sampling time between the first sampling time and the second sampling time; and
when it is determined that there is a first simulated sampling time between the first sampling time and the second sampling time:
obtaining a third voltage reading at the first simulated sampling time by interpolating the first voltage reading sample and the second voltage reading sample;
applying the third voltage reading to a low-pass filter;
obtaining from the low-pass filter a first noise value at the first simulated sampling time;
storing the first noise value in memory;
obtaining from the low-pass filter a second noise value at a second simulated sampling time, the second simulated sampling time being equal to a sum of the first simulated sampling time and the second time interval, the second simulated sampling time occurring later than the second sampling time;
storing the second noise value in memory;
obtaining a third noise value at the second sampling time by interpolating the first noise value and the second noise value; and
subtracting the third noise value from the second voltage reading at the second sampling time.

6. The method of claim 5, wherein determining the second sampling rate comprises:
determining an integer number of simulated samples to be obtained within the one frame of the electrical signal;
determining a time duration for each period of the electrical signal;
determining a time duration between each of the simulated samples, the time duration between each of the simulated samples being equal to the time duration of each period of the electrical signal multiplied by a number of periods in one frame divided by the number of simulated samples; and
obtaining a reciprocal of the time duration between each of the simulated samples.

7. The method of claim 6, wherein the number of simulated samples to be obtained within one frame of the electrical signal is 50 and the number of periods in one frame is 3.

8. The method of claim 5, wherein an estimate is received for a noise frequency and wherein the second sampling rate is determined based on the estimated noise frequency,

9. The method of claim 5, wherein determining whether there is a simulated sampling time between the first sampling time and the second sampling time comprises:
determining a third simulated sampling time, the third simulated sampling time being less than the first sampling time.
adding the third simulated sampling time and the second time interval;
determining whether the sum of the third simulated sampling time and the second time interval is less than the second sampling time; and
when the sum of the third simulated sampling time and the second time interval is less than the second sampling time, determining that there is a simulated sampling time between the first sampling time and the second sampling time.

10. The method of claim 5, wherein obtaining from the low-pass filter a second noise value at a second simulated sampling time comprises:
obtaining the second simulated sampling time, the second simulated sampling time being equal to a sum of the first simulated sampling time and the second time interval;
obtaining from the low pass filter a second noise value at the second simulated sampling time

11. The method of claim 5, further comprising:
determining that there is a third simulated sampling time between the first sampling time and the second sampling time, the third simulated sampling time being equal to a sum of the first simulated sampling time and the second time interval;
obtaining a fourth voltage reading at the third simulated sampling time by interpolating the first voltage reading sample and the second voltage reading sample;
applying the fourth voltage reading to the low pass filter;
obtaining from the low pass filter a fourth noise value at the third simulated sampling time;
storing the fourth noise value in memory;
determining a fourth simulated sampling time, the fourth simulated sampling time being equal to a sum of the third simulated sampling time and the second time interval;
obtaining from the low-pass filter a fifth noise value at the fourth simulated sampling time;
storing the fifth noise value in memory;
obtaining a sixth noise value by interpolating the fourth noise value and the fifth noise value at the second sampling time; and
subtracting the sixth noise value from the second voltage reading sample at the second sampling time.

12. The method of claim 5, wherein when it is determined that there is a not a first simulated sampling time between the first sampling time and the second sampling time:
determining a third simulated sampling time, the third simulated sampling time being less than the first sampling time.
determining a fourth simulated sampling time; the fourth simulated sampling time being equal to a sum of the third simulated sampling time and the second time interval, the fourth simulated sampling time being greater than the second sampling time;
obtaining from memory the fourth noise value at the third simulated sampling time;
obtaining from memory a fifth noise value at the fourth simulated sampling time; and
calculating a sixth noise value at the second sampling time by interpolating the fourth noise value and the fifth noise value; and
subtracting the sixth noise value from the second voltage reading sample at the second sampling time.

13. The method of claim 5, further comprising averaging, using a weighted average, the first noise value with a noise value stored in memory and storing the averaged noise value in memory.

14. The method of claim 13, further comprising updating the first noise value over a plurality of frames of the electrical signal.

15. The method of claim 5, wherein the first noise value is stored at a first index location in a computer memory array.

16. The method of claim 5, further comprising:
determining a second number of line noise samples, the second number of line noise samples being equal to the first number of line noise samples multiplied by a scaling factor greater than 1;
determining a third sampling rate for the electrical signal, the third sampling rate being equal to the second sampling rate multiplied by the scaling factor greater than 1;
determining a third time interval for the electrical signal, the third time interval being equal to a reciprocal of the third sampling rate;
using the third time interval to determine third index array locations in a computer memory array, there being one third index array location for each third time interval time period within one frame of the electrical signal;
obtaining a fourth voltage reading at the first sampling rate;
applying the fourth voltage reading to the low-pass filter;
determining a fourth noise value for the fourth voltage reading from the line filter;
determining a third sampling time that is closest to a time at which the fourth voltage reading is obtained; and
determining a third array index location corresponding to the third sampling time;
storing the fourth noise value in the third array index location; and
subtracting the fourth noise value from the fourth voltage reading,

17. The method of claim 16, further comprising:
obtaining a plurality of voltage readings over a plurality of frames at the first sampling rate;
for each of the plurality of voltage readings, obtaining a noise value for each of the plurality of voltage readings from the line filter;
determining a computer memory array location that is closest in time to a time at which each of the plurality of voltage readings is obtained;
obtaining a simulated noise value from each of the computer memory array locations;
averaging, using a weighted average, each simulated noise value with each associated voltage reading; and
storing each averaged noise value in the associated computer memory array location.

18. The method of claim 16, wherein averaging comprises:
multiplying the noise value obtained from the low-pass filter by a first weighting factor to create a first product, multiplying the simulated noise value by a second weighting factor to create a second product; and
obtaining a sum of the first product and the second product.

19. A method implemented on an electronic computing device for reducing noise from an electrical signal, the method comprising:
determining a number of noise samples;
determining a first sampling rate for the electrical signal;
determining a first time interval for the electrical signal, the first time interval being equal to a reciprocal of the first sampling rate;
determining a second sampling rate for the electrical signal, the second sampling rate being equal to the first sampling rate multiplied by a scaling factor greater than 1;
determining a second time interval for the electrical signal, the second time interval being equal to a reciprocal of the second sampling rate;
using the second time interval to determine index array locations in a computer memory array, there being one index array location for each second time interval time period within one frame of the electrical signal;
obtaining a voltage reading at the first sampling rate;
determining a first sampling time corresponding to the voltage reading;
determining a second sampling time within a frame that is closest in time to the first sampling time;
determining an array index location corresponding to the second sampling time;
applying the voltage reading to a low pass filter at the array index location corresponding to the second sampling time;
determining a noise value for the voltage reading from the low pass filter;
subtracting the noise value from the voltage reading.

20. The method of claim 19, wherein averaging comprises:
multiplying the noise value obtained from the low-pass filter by a first weighting factor to create a first product, multiplying the simulated noise value by a second weighting factor to create a second product; and
obtaining a sum of the first product and the second product.

21. A method implemented on an electronic computing device for reducing noise from an electrical signal, the method comprising:
obtaining a sampling rate for the electrical signal, the sampling rate being a rate at which voltage readings are obtained for the electrical signal, each voltage reading comprising a data component and a noise component;
determining a time interval from the sampling rate, the time interval being equal to a reciprocal of the sampling rate;
determining a number of voltage readings to be obtained within a first frame of the electrical signal, the first frame being any random frame in the electrical signal, the first frame of the electrical signal comprising an integer number of periods of the noise component of the electrical signal for which there are equally spaced voltage readings corresponding to the time interval, each voltage reading being obtained one time interval of time after a previous voltage reading is obtained;
at each time interval within the first frame:
obtaining a voltage reading;
applying the obtained voltage reading to a low-pass filter;
obtaining from the low-pass filter a noise value; and
subtracting the noise value from the voltage reading.

22. The method of claim 21, further comprising:
storing the noise value in an indexed memory location;
determining a time for a second frame in the electrical signal, the second frame occurring immediately following the first frame; and
at each time within the second frame:
obtaining a voltage reading;
applying the obtained voltage reading to the low-pass filter;
obtaining from the low-pass filter a noise value;
averaging the obtained noise value with a noise value obtained from the indexed memory location corresponding to a same time offset in the first frame, the averaging comprising a weighted average;
storing the averaged noise value in the indexed memory location corresponding to the same time offset in the first frame; and
subtracting the averaged noise value from the voltage reading.

23. (canceled)
